(19) United States
(12) Patent Application Publication
(10) Pub. No.: US 2009/0039495 A1
(43) Pub. Date: Feb. 12, 2009

(54) WIRING SUBSTRATE AND DISPLAY DEVICE INCLUDING THE SAME

(75) Inventors: Kenichi Yamashita, Nara (JP); Yoshiki Nakatani, Nara (JP); Tetsuya Aita, Osaka (JP)

Correspondence Address: SHARP KABUSHIKI KAISHA;C/O KEATING & BENNETT, LLP, 1800 Alexander Bell Drive, SUITE 200, Reston, VA, 20191, US

(73) Assignee: SHARP KABUSHIKI KAISHA, Osaka-shi, Osaka (JP)

(21) Appl. No.: 12/089,059

(22) PCT Filed: Jun. 13, 2006
(86) PCT No.: PCT/JP2006/311801

§ 371 Date: Apr. 3, 2008

(30) Foreign Application Priority Data
Oct. 5, 2005 (JP) 2005-292153

(51) Int. Cl. H01L 23/48; H01L 23/52

(52) U.S. Cl. 257/690; 257/737; 257/784; 257/E23.023

(57) ABSTRACT

An active matrix substrate includes a first substrate and a driving integrated circuit chip mounted on the first substrate. A support member is provided between the active matrix substrate and the driving IC chip so as to be in contact with both the active matrix substrate and the driving IC chip.

### BACKGROUND OF THE INVENTION

1. Field of the Invention

The present invention relates to a wiring substrate and a display device including the same.

2. Description of the Related Art

Conventionally, various mounting methods of an integrated circuit chip (hereinafter, sometimes referred to as an “IC chip”) have been proposed (e.g., Japanese Laid-Open Patent Publication No. 10-319419, Japanese Laid-Open Patent Publication No. 2000-323523, and Japanese Laid-Open Patent Publication No. 2002-198397). For example, the proposed methods include a method in which a bump electrode of a semiconductor element is directly bonded to an electrode of a circuit board, a flip chip mounting method using an anisotropic electrically conductive film (hereinafter, sometimes referred to as “ACF”) and an anisotropic electrically conductive paste (hereinafter, sometimes referred to as “ACP”), and a method in which a terminal portion is bonded to a bump electrode with solder or the like.

In these methods, an IC chip is mounted through a heat pressure bonding process. More specifically, an IC chip is mounted on a substrate by the following heat pressure bonding process: an IC chip is placed at a prescribed position on a substrate and temporarily fixed at that position. In this state, the substrate is placed on a pressure bonding stage, and the IC chip is pressed with a heated pressure bonding tool.

In order to mount an IC chip in a preferable manner, it is preferable to apply a uniform pressure to each part of the IC chip (more specifically, between each terminal portion and a corresponding bump electrode) in the heat pressure bonding process of the IC chip. It is therefore preferable to conduct the heat pressure bonding process with the pressure bonding stage and the pressure bonding tool being held parallel with each other. However, it is difficult to hold the pressure bonding stage and the pressure bonding tool completely parallel to each other, and the pressure bonding stage and the pressure bonding tool are usually somewhat tilted with respect to each other in the heat pressure bonding process. In this case, the pressure is not uniformly applied between each terminal portion and bump electrode. In other words, the applied pressure is excessive in some regions and is not enough to bond the terminal portions to the bump electrodes in other regions. Such an excessive pressure may damage or disconnect the terminal portions and the bump electrodes and an insufficient pressure may cause unreliable electrical conduction between the terminal portion and the bump electrode.

The substrate and the IC chip are heated in the mounting process. Therefore, the substrate and the IC chip may be deformed due to warping especially in the case where the IC chip is mounted on a thin glass substrate or a plastic substrate. In this case as well, the pressure is not uniformly applied between each terminal portion and a corresponding bump electrode. Such non-uniform pressure application may cause problems such as unreliable electrical conduction due to an insufficient pressure and damage or disconnection of the terminal portions and the bump electrodes due to an excessive pressure.

Various technologies have been disclosed in attempts to solve the above problems (e.g., Japanese Laid-Open Patent Publication No. 10-319419, Japanese Laid-Open Patent Publication No. 2000-323523, and Japanese Laid-Open Patent Publication No. 2002-198397).

For example, in the technology disclosed in Japanese Laid-Open Patent Publication No. 10-319419, metal projection electrodes at the corners of an IC chip are used as dummy electrodes because it is difficult to assure electrical conduction in these regions due to warping of the IC chip and/or the substrate. However, non-uniformity of pressure application to the terminal portions is not significantly reduced by the technology of Japanese Laid-Open Patent Publication No. 10-319419. Therefore, an excessive pressure is applied to some regions, whereby terminal portions and bump electrodes may be damaged or disconnected and reliable electrical conduction between the terminal portion and the bump electrode may not be obtained in these regions.

Japanese Laid-Open Patent Publication No. 2000-323523 discloses a technology in which spherical spacers are contained in an ACF provided between a circuit board and a semiconductor chip (an IC chip). Japanese Laid-Open Patent Publication No. 2000-323523 describes that the spacers prevent an active surface of the semiconductor chip and a counter surface of the circuit board from directly contacting each other except in a connected portion, whereby deformation of elements such as the semiconductor chip is suppressed. In the case where the spacers are located in a region other than the connected portion, it is expected to some extent that the tilt between the semiconductor chip and the circuit board is reduced and non-uniformity of pressure application is reduced in the heat pressure bonding process. However, the spacers may not always be disposed in a region other than the connected portion, and the spacers may be disposed between the terminal portion and the bump electrode. In this case, the spacers prevent electric connection between the terminal portion and the bump electrode from being obtained and may increase the tilt between the semiconductor chip and the circuit board. It is therefore difficult to mount the semiconductor chip with high reliability using the technology of Japanese Laid-Open Patent Publication No. 2000-323523.

Japanese Laid-Open Patent Publication No. 2002-198397 discloses a technology in which voids (bubbles) are formed in an ACF provided between a semiconductor element and a substrate. Japanese Laid-Open Patent Publication No. 2002-198397 describes that connection of the mounted semiconductor element can be stably retained by the buffer action of the voids formed in the ACF. However, it is very difficult to form the voids (bubbles) so as to obtain sufficient buffering action. For example, since position control of the voids is difficult, the voids may be located between the terminal portion and the bump electrode. In this case, electric connection cannot be obtained between the terminal portion and the bump electrode due to the voids.

### SUMMARY OF THE INVENTION

In order to overcome the problems described above, preferred embodiments of the present invention provide a wiring substrate having an IC chip mounted thereon with high reliability.

A wiring substrate according to a preferred embodiment of the present invention includes a substrate, a plurality of wirings provided on the substrate, an integrated circuit chip arranged so as to face the substrate and having a plurality of bump electrodes electrically connected to the respective terminal portions, and a support member (preferably having an insulating property). The plurality of wirings extend in parallel or substantially in parallel with each other and each of the wirings has a terminal portion. The support member is provided between the substrate and the integrated circuit chip so as to be in contact with both the substrate and the integrated circuit chip.

Note that in the wiring substrate according to the present preferred of the present invention, the bump electrodes may be electrically connected to the respective terminal portions by direct contact. For example, the bump electrodes may alternatively be electrically connected to the respective terminal portions with an electrically conductive member (such as electrically conductive fine particles and solder) interposed therebetween. The substrate may be made of plastic or glass.

In order to mount the integrated circuit chip in a preferable manner, it is preferable to uniformly apply a pressure to the integrated circuit chip in the heat pressure bonding process of the integrated circuit chip. For uniform pressure application, the heat pressure bonding process is preferably conducted with a pressure bonding stage and a pressure bonding tool being held parallel to each other. However, it is difficult to hold the pressure bonding stage and the pressure bonding tool completely parallel to each other, and the pressure bonding stage and the pressure bonding tool are usually somewhat tilted with respect to each other in the heat pressure bonding process. In this case, the pressure is not uniformly applied between each terminal portion and bump electrode. In other words, the applied pressure is excessive in some regions and is not enough to bond the terminal portions to the bump electrodes in other regions. Such an excessive pressure may damage or disconnect the terminal portions and the bump electrodes and may cause unreliable electrical conduction between the terminal portion and the bump electrode in some regions.

The wiring substrate according to a preferred embodiment of the present invention includes the support member that is in contact with both the integrated circuit chip and the substrate. Therefore, non-uniformity of pressure application due to the tilt between the pressure bonding tool and the pressure bonding stage can be effectively reduced in the wiring substrate according to a preferred embodiment of the present invention. As a result, a pressure that is preferable for bonding can be uniformly applied between the terminal portion and the bonding electrode, whereby the integrated circuit chip can be mounted with high reliability.

In order to implement higher reliability, the support member is preferably arranged so as to uniformly support the integrated circuit chip. More specifically, the support member may be provided between at least a portion of a periphery of the integrated circuit chip and the substrate. The support member may be shaped like a wall and extend as a band so as to surround the integrated circuit chip. The support member may be provided between each of four corners of the integrated circuit and the substrate.

The support member may be provided between adjacent wirings on the substrate. For example, in the case where the substrate is made of plastic or in the case where the substrate is made of a thin glass, the substrate may be deformed such as being warped or bent during the heat pressure bonding process. By providing the support member between adjacent wirings, the substrate can be flattened even when the substrate is deformed, whereby non-uniformity of pressure application can be reduced. As a result, the integrated circuit chip can be mounted with high reliability.

The support member may be provided both between each terminal portion and wiring and between at least a portion of a periphery of the integrated circuit chip and the substrate.

The wiring substrate according to a preferred embodiment of the present invention may include an anisotropic electrically conductive adhesive layer provided between the substrate and the integrated circuit chip and made of an insulating resin having electrically conductive fine particles dispersed therein, for electrically connecting the terminal portions to the plurality of bump electrodes. In other words, the integrated circuit chip may be mounted through the anisotropic electrically conductive layer. In this case, it is preferable that the wiring substrate according to a preferred embodiment of the present invention also includes an insulating member for isolating each terminal portion from a wiring and a bump electrode that are adjacent to the terminal portion and isolating a bump electrode facing the terminal portion from a bump electrode and a wiring that are adjacent to the bump electrode.

In the case where the integrated circuit chip is mounted through the anisotropic electrically conductive layer, the electrically conductive fine particles in the anisotropic electrically conductive layer may cause short-circuiting between adjacent bump electrodes, adjacent terminal portions, and the like, and a leakage current may be generated. In this structure, however, the insulating member isolates each terminal portion from a wiring and a bump electrode that are adjacent to the terminal portion and also isolates a bump electrode facing the terminal portion from a bump electrode and a wiring that are adjacent to the bump electrode. Therefore, such short-circuiting between adjacent bump electrodes, between adjacent terminal portions, and the like caused by the electrically conductive fine particles can be suppressed, whereby generation of leakage current can be prevented.

In preferred embodiments of the present invention, “isolating a terminal portion from a wiring and a bump electrode that are adjacent to the terminal portion” means to isolate a terminal portion from a wiring and a bump electrode that are adjacent to the terminal portion to such a degree that the terminal portion and the adjacent wiring and bump electrode are not short-circuited by the electrically conductive fine particles, and is not limited to spatially completely isolating a terminal portion from a wiring and a bump electrode that are adjacent to the terminal portion. Similarly, “isolating a bump electrode from a bump electrode and a wiring that are adjacent to the bump electrode” means to isolate a bump electrode from a bump electrode and a wiring that are adjacent to the bump electrode to such a degree that the bump electrode and the adjacent bump electrode and wiring are not short-circuited by the electrically conductive fine particles, and is not limited to spatially completely isolating a bump electrode from a bump electrode and a wiring that are adjacent to the bump electrode.

The insulating member may be provided between each terminal portion and a wiring adjacent to the terminal portion on the substrate. In this case, a gap between a top of the insulating member and the integrated circuit chip is preferably equal to or less than a particle size of the electrically conductive fine particles.

In the case where the gap between the top of the insulating member and the integrated circuit chip is equal to or less than the particle size of the electrically conductive fine particles, the electrically conductive fine particles can be effectively prevented from being disposed between the insulating member and the integrated circuit chip. Therefore, short-circuiting can be effectively prevented between a terminal portion and a wiring adjacent to the terminal portion which are isolated from each other by the insulating member and between a terminal portion and a bump electrode facing the terminal portion which are isolated from each other by the insulating member. In order to effectively prevent the electrically conductive fine particles from being disposed between the insulating member and the integrated circuit chip, it is preferable that the insulating member has an approximately trapezoidal shape in cross section with a width reduced from the substrate toward the integrated circuit chip. In other words, it is preferable that a top surface of the insulating member has a narrower width. It is more preferable that a width of the top surface of the insulating member is equal to or less than the particle size of the electrically conductive fine particles.

Note that the particle size of the electrically conductive fine particles specifically refers to a mean particle size of the electrically conductive fine particles. The particle size of the electrically conductive fine particles can be measured with a laser diffraction/scattering particle size distribution analyzer LA-300 made by HORIBA, Ltd.

In the wiring substrate according to a preferred embodiment of the present invention, the insulating member may be provided between adjacent bump electrodes on the integrated circuit chip. In this case, a gap between a top of the insulating member and the substrate may be equal to or less than the particle size of the electrically conductive fine particles.

As in the case described above, by making the gap between the top of the insulating member and the substrate equal to or less than the particle size of the electrically conductive fine particles, the electrically conductive fine particles can be prevented from being disposed between the insulating member and the substrate. Accordingly, short-circuiting can be effectively prevented between adjacent bump electrodes isolated from each other by the insulating member and between a bump electrode and a terminal portion that faces a bump electrode adjacent to the bump electrode. In order to effectively prevent the electrically conductive fine particles from being disposed between the insulating member and the integrated circuit chip, it is preferable that the insulating member has an approximately trapezoidal shape in cross section with a width reduced from the integrated circuit chip toward the substrate. In other words, it is preferable that a top surface of the insulating member has a narrower width. It is more preferable that a width of the top surface of the insulating member is equal to or less than the particle size of the electrically conductive fine particles.

In the wiring substrate according to a preferred embodiment of the present invention, it is preferable that the insulating member is in contact with both the substrate and the integrated circuit chip. With this structure, the insulating member can more effectively implement isolation between adjacent terminal portions, between adjacent bump electrodes, and between a terminal portion and a bump electrode that faces a terminal portion adjacent to that terminal portion. Therefore, generation of leakage current can be more effectively suppressed. In this case, the insulating member functions also as a support member. Therefore, for example, in the case where the substrate is made of plastic or the like and the substrate is deformed such as being warped or bent, the substrate is flattened by the support member functioning as a support member, and non-uniformity of pressure application can be reduced.

As a result, the integrated circuit chip can be mounted with high reliability.

In the wiring substrate according to a preferred embodiment of the present invention, each terminal portion may be wider than a portion other than the terminal portion of the wiring and the terminal portions may be linearly arranged in a width direction of the terminal portions, and the insulating member may be provided only between adjacent terminal portions.

In the case where each terminal portion is wider than the portion other than the terminal portion of the wiring and the terminal portions are linearly arranged in the width direction of the terminal portions, the space between adjacent terminal portions having a relatively wide width is narrower than the space between the terminal portion of the wiring and the portion other than the terminal portion of an adjacent wiring and the space between the portions other than the terminal portions of adjacent terminals. Therefore, a leakage current is likely to be generated especially between adjacent terminal portions. In this structure, however, the insulating member is provided in the relatively narrow space between adjacent terminal portions. Therefore, short-circuiting between adjacent terminal portions can be effectively suppressed, whereby generation of leakage current can be effectively prevented.

In the wiring substrate according to a preferred embodiment of the present invention, each terminal portion may be wider than a portion other than the terminal portion of the wiring and the terminal portions may be arranged in a staggered pattern along a width direction of the terminal portions, and the insulating member may be provided only between each terminal portion and a wiring adjacent to the terminal portion.

In the case where each terminal portion is wider than the portion other than the terminal portion of the wiring and the terminal portions are arranged in a staggered pattern along the width direction of the terminal portions, the space between each terminal portion and a wiring adjacent to the terminal portion is relatively narrow and a leakage current is likely to be generated especially in that region. In this structure, however, the insulating member is provided in the relatively narrow space between each terminal portion and a wiring adjacent to the terminal portion. Therefore, generation of leakage current can be effectively prevented.

The anisotropic electrically conductive layer may be formed by a wet process. The anisotropic electrically conductive layer can be easily formed at low cost by using a wet process.

Note that a “wet process” is a layer formation method that uses ink containing a material for forming a layer (the material is herein an insulating resin and electrically conductive fine particles). Examples of the wet process include a spin coating method, a doctor blade method, a discharge coating method, a spray coating method, an ink jet method, a letterpress printing method, an intaglio printing method, a screen printing method, a microgravure coating method, and the like.

In the case where the anisotropic electrically conductive layer is formed by a wet process, it is preferable that at least a side surface and a top surface of the insulating member have a liquid repellent property. In other words, it is preferable that the side surface and the top surface of the insulating member have a property to repel ink that is used in the wet process. Examples of a method for applying a liquid repellent property (a property to repel ink for forming a layer) to the side surface and the top surface of the insulating member include a method in which the insulating member is made of a material having a liquid repellent property and a method in which liquid repellent treatment such as plasma treatment is conducted to the insulating member.

A first display device according to a preferred embodiment of the present invention includes a wiring substrate, a display medium layer, and a second electrode. The wiring substrate includes a substrate, a plurality of wirings provided on the substrate, an integrated circuit chip provided so as to face the substrate, a plurality of bump electrodes provided on a surface of the integrated circuit chip on a side of the substrate, a support member, and a first electrode. The plurality of wirings extend in parallel or substantially parallel with each other and each wiring has a terminal portion. The plurality of bump electrodes are electrically connected to the respective terminal portions. The first electrode is electrically connected to the plurality of wirings. The support member is provided between the substrate and the integrated circuit chip so as to be in contact with both the substrate and the integrated circuit chip. The display medium layer is provided between the first electrode and the second electrode.

In this specification, a “display medium layer” is a layer in which light transmittance is modulated by a potential difference between opposing electrodes, or a layer that emits light by a current flowing between opposing electrodes. Examples of the display medium layer include a liquid crystal layer, an inorganic or organic EL (electroluminescence) layer, a light-emitting gas layer, an electrophoretic layer, an electrochromic layer, and the like.

A second display device according to a preferred embodiment of the present invention includes a first wiring substrate, a second wiring substrate having the first wiring substrate mounted thereon, a display medium layer, and a second electrode. The first wiring substrate includes a substrate, a plurality of first wirings provided on the substrate, an integrated circuit chip provided so as to face the substrate, a plurality of bump electrodes provided on a surface of the integrated circuit chip on a side of the substrate, a support member, and a plurality of first electrodes. The plurality of first wirings extend in parallel or substantially parallel with each other and each of the plurality of first wirings has a terminal portion. The plurality of bump electrodes are electrically connected to the respective terminal portions. The support member is provided between the substrate and the integrated circuit chip so as to be in contact with both the substrate and the integrated circuit chip. A plurality of second wirings are respectively electrically connected to the plurality of first wirings. The first electrodes are electrically connected to the plurality of second wirings. The display medium layer is provided between the first electrodes and the second electrode.

Other features, elements, processes, steps, characteristics and advantages of the present invention will become more apparent from the following detailed description of preferred embodiments of the present invention with reference to the attached drawings.

### BRIEF DESCRIPTION OF THE DRAWINGS

FIG. 1 is a plan view of a liquid crystal display device according to a first preferred embodiment of the present invention.

FIG. 2 is a cross-sectional view taken along line II-II in FIG. 1.

FIG. 3 is an enlarged plan view of a region around a driving IC chip.

FIG. 4 is a cross-sectional view taken along line IV-IV in FIG. 3.

FIGS. 5A and 5B are schematic cross-sectional views illustrating a mounting process in the case where a support member is not provided.

FIGS. 6A, 6B, and 6C are schematic cross-sectional views illustrating a mounting process in the first preferred embodiment of the present invention.

FIG. 7 is an enlarged plan view of a region around a driving IC chip of a liquid crystal display device according to a first modification of preferred embodiments of the present invention.

FIG. 8 is an enlarged plan view of a region around a driving IC chip of a liquid crystal display device according to a second modification of preferred embodiments of the present invention.

FIG. 9 is an enlarged plan view of a region around a driving IC chip of a liquid crystal display device according to a third modification of preferred embodiments of the present invention.

FIG. 10 is an enlarged plan view of a region around a driving IC chip of a liquid crystal display device according to a second preferred embodiment of the present invention.

FIG. 11 is a cross-sectional view taken along line XI-XI in FIG. 10.

FIG. 12 is an enlarged plan view of a region around a driving IC chip of a liquid crystal display device according to a fourth modification of preferred embodiments of the present invention.

FIG. 13 is a cross-sectional view taken along line XIII-XIII in FIG. 12.

FIG. 14 is an enlarged plan view of a region around a driving IC chip of a liquid crystal display device according to a fifth modification of preferred embodiments of the present invention.

FIG. 15 is a cross-sectional view taken along line XV-XV in FIG. 14.

FIG. 16 is an enlarged cross-sectional view of a region around a driving IC chip of a liquid crystal display device according to a sixth modification of preferred embodiments of the present invention.

FIG. 17 is an enlarged cross-sectional view of a region around a driving IC chip of a liquid crystal display device according to a third preferred embodiment of the present invention.

FIG. 18 is an enlarged plan view of a region around a driving IC chip of a liquid crystal display device according to a fourth preferred embodiment of the present invention.

FIG. 19 is a cross-sectional view taken along line XIX-XIX in FIG. 18.

FIGS. 20A, 20B, and 20C are schematic cross-sectional views illustrating a mounting process in the fourth preferred embodiment of the present invention.

FIG. 21 is a plan view of a liquid crystal display device according to a fifth preferred embodiment of the present invention.

FIG. 22 is a cross-sectional view taken along line XXII-XXII in FIG. 21.

FIG. 23 is an enlarged plan view of a region around a driving IC chip.

FIG. 24 is a cross-sectional view taken along line XXIV-XXIV in FIG. 23.

### DETAILED DESCRIPTION OF THE PREFERRED EMBODIMENTS

Hereinafter, preferred embodiments of the present invention will be described in detail with reference to the figures.

### First Preferred Embodiment

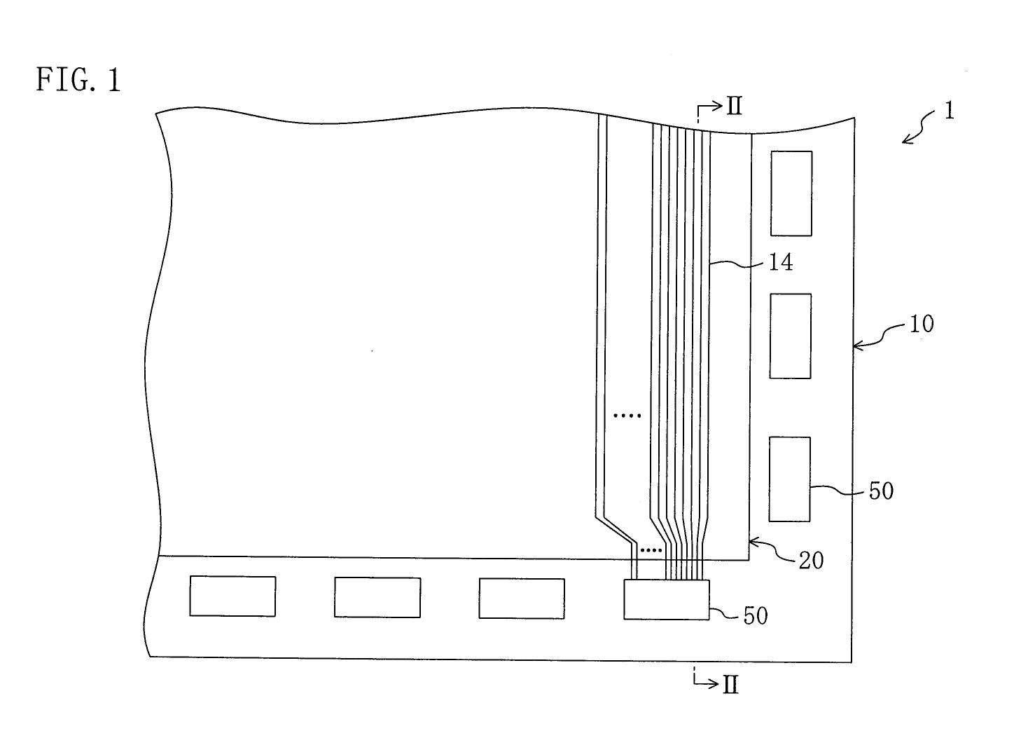

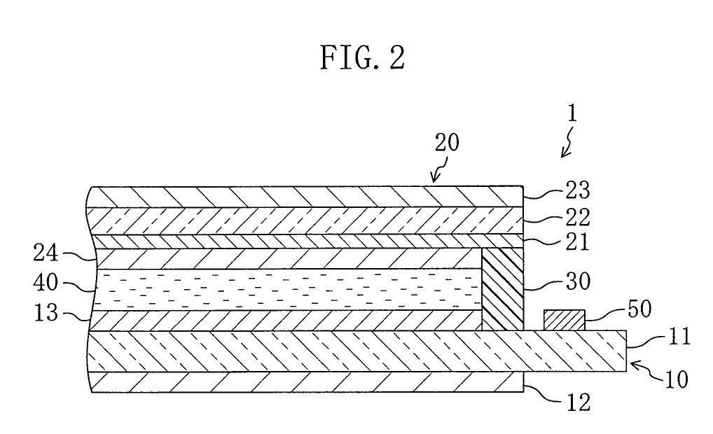

FIG. 1 is a plan view of a liquid crystal display device 1 according to a first preferred embodiment of the present invention. FIG. 2 is a cross-sectional view taken along line II-II in FIG. 1.

The liquid crystal display device 1 according to the first preferred embodiment preferably includes an active matrix substrate 10, a counter substrate 20 facing the active matrix substrate 10, a liquid crystal layer 40 interposed between the active matrix substrate 10 and the counter substrate 20 as a display medium layer, and a seal member 30 bonding the active matrix substrate 10 and the counter substrate 20 to each other and sealing the liquid crystal layer 40.

The active matrix substrate 10 has a first substrate 11 made of plastic or glass and a first polarizing plate 12 provided on the opposite side to the liquid crystal layer 40 on the first substrate 11. A plurality of gate lines and a plurality of source lines are provided on the active matrix substrate 10. The plurality of gate lines extend in parallel or substantially in parallel with each other and the plurality of source lines extend in parallel or substantially in parallel with each other at an angle (typically at a right angle) to the extending direction of the gate lines (in this specification, electrode lines such as the gate lines and the source lines are collectively referred to as “wirings” 14). A switching element (not shown) such as a TFT (Thin Film Transistor) element is provided near each intersection of the gate lines and the source lines. Each switching element is electrically connected to a corresponding gate line and a corresponding source line. A plurality of pixel electrodes 13 are arranged in a prescribed pattern (typically, in a matrix pattern) on the surface of the active matrix substrate 10 located on the side of the liquid crystal layer 40. Each pixel electrode 13 is electrically connected to a corresponding switching element (not shown) and is driven by that switching element.

The counter substrate 20 has a second substrate 22, a second polarizing plate 23 provided on the opposite side to the liquid crystal layer 40 on the second substrate 22, and an upper common electrode 21 provided on the surface of the second substrate 22 on the side of the liquid crystal layer 40. The liquid crystal display device 1 is driven by a voltage that is applied to the liquid crystal layer 40 by the upper common electrode 21 and the plurality of pixel electrodes 13 provided on the active matrix substrate 10.

In the first preferred embodiment, the active matrix substrate 10 and the counter substrate 20 preferably have a substantially rectangular shape and the active matrix substrate 10 is larger than the counter substrate 20. The counter substrate 20 covers the liquid crystal layer 40 on the active matrix substrate 10. Driving integrated circuit chips (hereinafter, sometimes referred to as “driving IC chips”) 50 are preferably bare-chip mounted on the periphery of the active matrix substrate 10 which is not covered by the counter substrate 20.

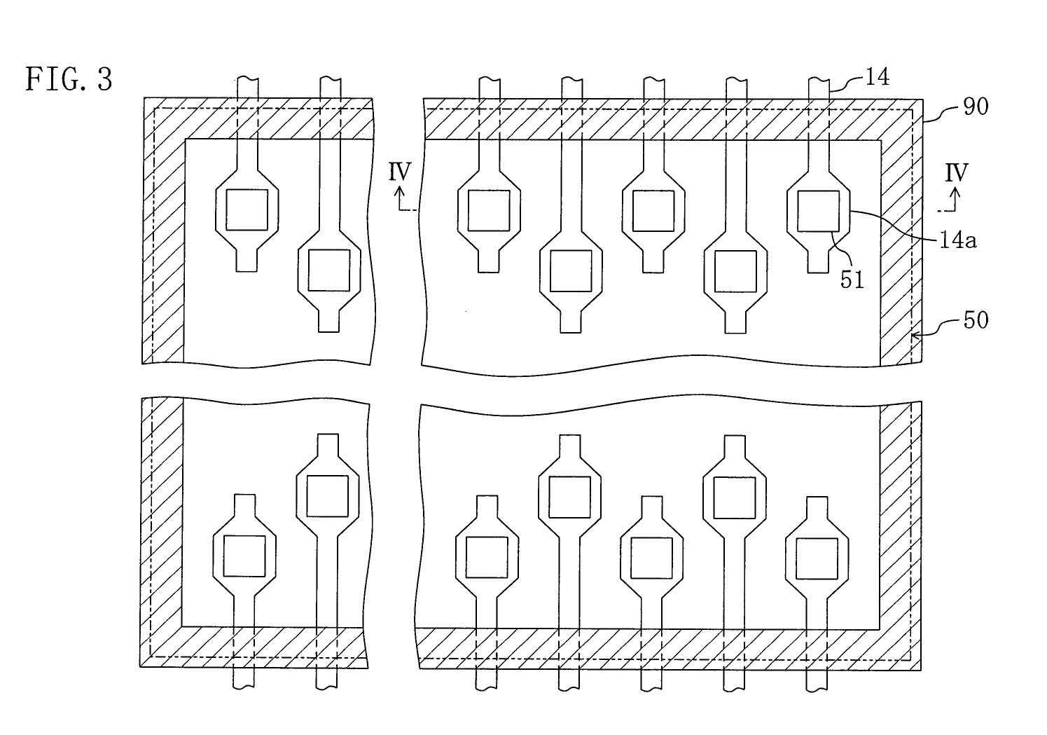

FIG. 3 is an enlarged plan view of a region around a driving IC chip 50.

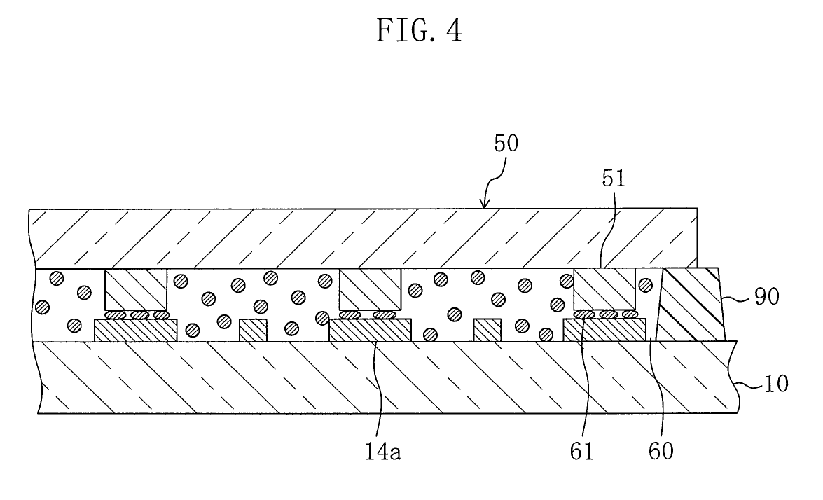

FIG. 4 is a cross-sectional view taken along line IV-IV in FIG. 3.

As shown in FIGS. 3 and 4, the driving IC chip 50 as an integrated circuit chip has a plurality of bump electrodes 51 as input/output terminals. The bump electrodes 51 are arranged in a staggered pattern along the direction of the longer side of the driving IC chip 50 (the width direction of terminal portions 14a). The bump electrodes 51 function also as bonding bump electrodes. The bump electrodes 51 are respectively electrically connected through an anisotropic electrically conductive layer 60 to the terminal portions 14a of the wirings 14 provided on the periphery of the active matrix substrate 10. The anisotropic electrically conductive layer 60 is made of an insulating resin with electrically conductive fine particles 61 dispersed therein.

In the liquid crystal display device 1 of this preferred embodiment, a support member 90 is provided in contact with the driving IC chip 50 and the active matrix substrate 10. More specifically, the support member 90 is preferably shaped like a wall and extends as a band so as to surround the driving IC chip 50.

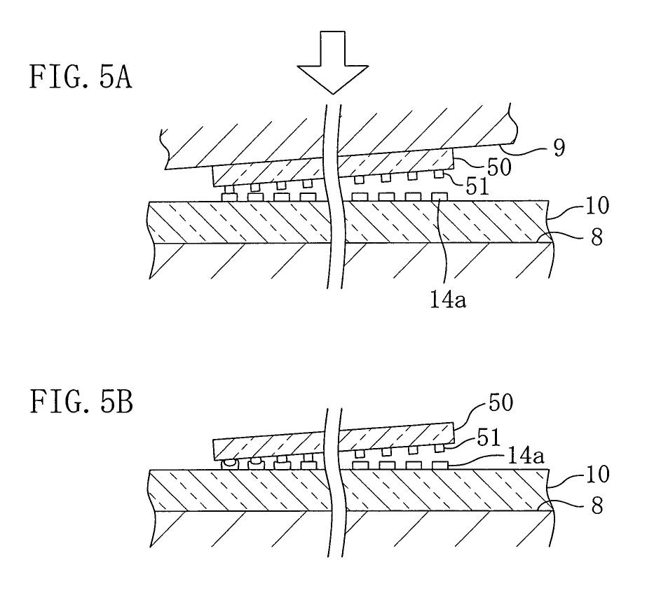

FIGS. 5A and 5B are schematic cross-sectional views illustrating a mounting process in the case where the support member 90 is not provided. FIG. 5A is a schematic cross-sectional view of the state before application of pressure. FIG. 5B is a schematic cross-sectional view of the state when mounting is completed.

Essentially, it is preferable that a pressure bonding stage 8 and a pressure bonding tool 9 are completely parallel to each other. However, it is difficult to hold the pressure bonding stage 8 and the pressure bonding tool 9 completely parallel to each other, and the pressure bonding stage 8 and the pressure bonding tool 9 are usually somewhat tilted with respect to each other as shown in FIG. 5A. In this state, the pressure is not uniformly applied to each terminal portion 14a. An excessive pressure is applied to a region where the active matrix substrate 10 and the driving IC chip 50 are relatively close to each other (a region on the left side of FIGS. 5A and 5B), while the pressure that is applied to a region where the active matrix substrate 10 and the driving IC chip 50 are relatively far from each other (a region on the right side of FIGS. 5A and 5B) is not enough to electrically connect the terminal portions 14a to the respective bump electrodes 51. In other words, in order to obtain electrical conduction between the terminal portions 14a and the bump electrodes 51, the electrically conductive fine particles 61 need to be pressed by the terminal portions 14a and the bump electrodes 51 enough to be flatten (deformed) to some extent. However, the pressure that is applied to the region on the right side of FIGS. 5A and 5B is not large enough to deform the electrically conductive fine particles 61.

Therefore, as shown in FIG. 5B, the terminal portions 14a and the bump electrodes 51 may be deformed, disconnected, and the like in the region on the left side of the figure due to the excessive pressure. Moreover, the terminal portions 14a and the bump electrodes 51 may not be electrically connected in a preferable manner in the region on the right side of the figure due to the insufficient pressure. Therefore, mounting may not be implemented in a preferable manner.

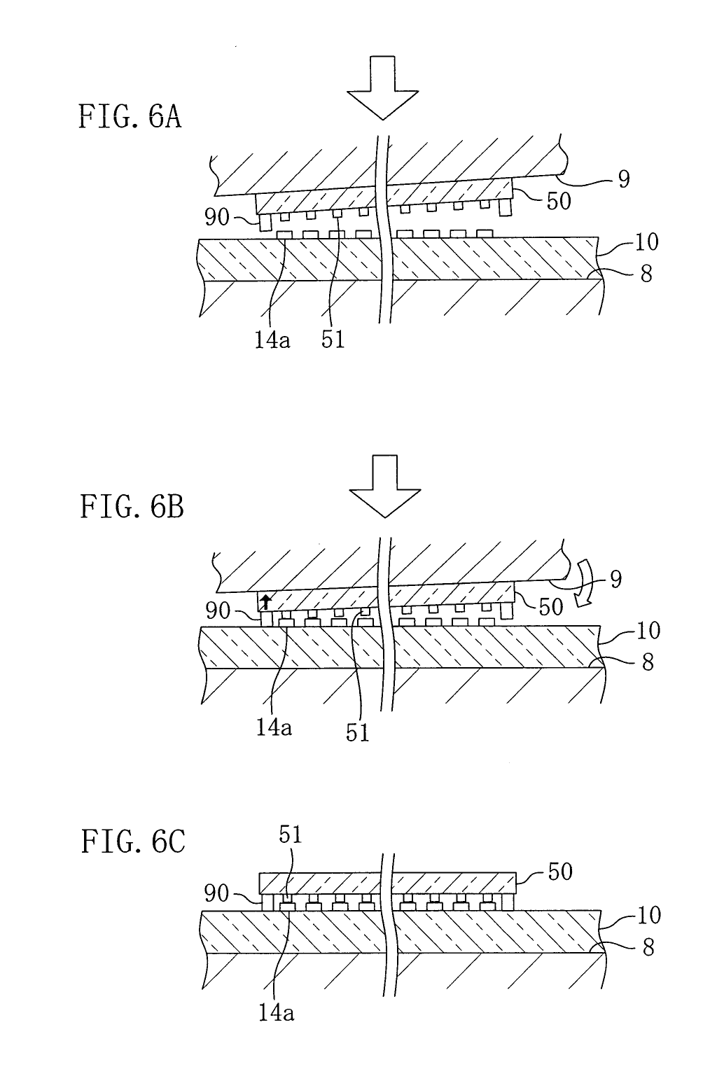

The liquid crystal display device of the first preferred embodiment has the support member 90 that is in contact with both the active matrix substrate 10 and the driving IC chip 50. Therefore, the driving IC chip 50 can be mounted with high reliability. The reason for this will now be described in detail with reference to FIGS. 6A, 6B, and 6C.

FIGS. 6A, 6B, and 6C are schematic cross-sectional views illustrating a mounting process in the first preferred embodiment. More specifically, FIG. 6A is a schematic cross-sectional view of the state before application of pressure. FIG. 6B is a schematic cross-sectional view of the state during application of pressure. FIG. 6C is a schematic cross-sectional view of the state when mounting is completed.

In the first preferred embodiment, even when the pressure bonding stage 8 and the pressure bonding tool 9 are somewhat tilted with respect to each other, the support member 90 that is taller than the terminal portions 14a corrects the parallelism between the pressure bonding stage 8 and the pressure bonding tool 9 to some extent, as shown in FIG. 6B. More specifically, as shown in FIG. 6B, when a portion of the support member 90 contacts the active matrix substrate 10, reaction force is applied to the pressure bonding tool 9 through that portion of the support member 90. Therefore, the tilt of the pressure bonding tool 9 with respect to the pressure bonding stage 8 is reduced and the pressure is relatively uniformly applied to each terminal portion 14a. As a result, the driving IC chip 50 can be mounted with high reliability.

The support member 90 preferably has an insulating property. In the case where the support member 90 is electrically conductive, short-circuiting may occur between the terminal portions 14a, between the terminal portion 14a and the bump electrode 51, and the like through the electrically conductive fine particles 61 dispersed in the anisotropic electrically conductive layer 60 and the support member 90. As a result, a leakage current may be generated. By using the support member 90 having an insulating property, such short-circuiting caused by the support member 90 can be prevented and generation of leakage current can be effectively suppressed.

In the first preferred embodiment, the support member 90 is arranged so that the outer edge thereof protrudes from the periphery of the driving IC chip 50 in view of an alignment margin. With this structure, the support member 90 can be reliably placed on the periphery of the driving IC chip 50 even when the driving IC chip 50 is misaligned with respect to the support member 90.

Hereinafter, a manufacturing process of the liquid crystal display device 1 of the first preferred embodiment, especially a manufacturing process of the support member 90 and a mounting process of the driving IC chip 50, will be described in detail.

First, various wirings 14 such as gate lines and source lines, TFTs, pixel electrodes 13, and the like are formed on the first substrate 11. The support member 90 is then formed. The support member 90 can be formed by forming an insulating resin film by a wet process such as a screen printing method and patterning the insulating film by a patterning technology such as a photolithography technology. The height of the support member 90 may be in the range of about 5 μm to about 25 μm (e.g., about 10 μm), for example. For example, the support member 90 is preferably made of an acrylic resin, a novolac resin, a polyimide resin, an epoxy resin, and the like. The periphery of the active matrix substrate 10 is then bonded to the periphery of the counter substrate 20 by the seal member 30 to form a space (an empty cell) for injection of a liquid crystal material. Thereafter, a liquid crystal material is injected (e.g., vacuum-injected) into the space (the empty cell) to form the liquid crystal layer 40.

The driving IC chip 50 is then mounted. More specifically, by a wet process such as an ink-jet method, the anisotropic electrically conductive layer 60 is formed on the periphery of the active matrix substrate 10 where the driving IC chip 50 is to be mounted. The driving IC chip 50 is then placed thereon and aligned. In this state, the active matrix substrate 10 is placed on a flat pressure bonding stage and the driving IC chip 50 is heated and pressed with a heated pressure bonding tool. The liquid crystal display device 1 is completed by thus mounting the driving IC chip 50.

In the case where a wet process is used to form the anisotropic electrically conductive layer 60, it is preferable to apply a liquid repellent property (a property to repel ink for forming the anisotropic electrically conductive layer 60) to the surface of the support member 90 in advance.

### First Modification

### Modification of the First Preferred Embodiment

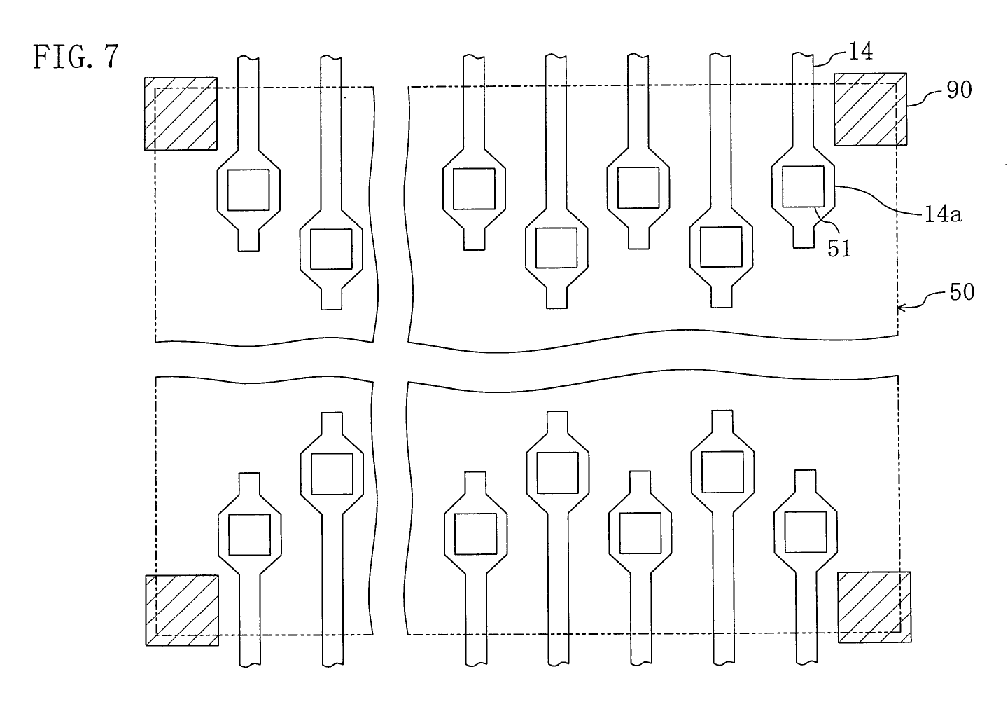

FIG. 7 is an enlarged plan view of a region around a driving IC chip 50 of a liquid crystal display device according to a first modification of the first preferred embodiment of the present invention.

As shown in FIG. 7, a support member 90 having a substantially rectangular cylindrical shape may be provided between each of the four corners of the driving IC chip 50 and the active matrix substrate 10. With this structure, the support member 90 does not overlap the wirings 14 and unnecessary pressure application to the wirings 14 can be suppressed.

### Second Modification

### Modification of the First Preferred Embodiment

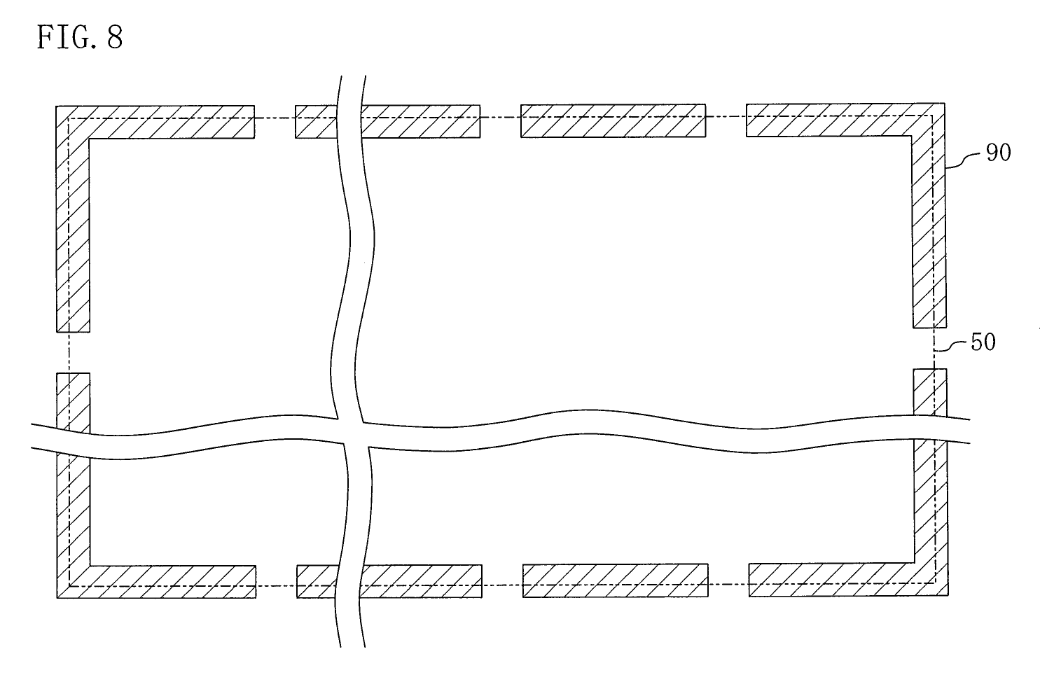

FIG. 8 is an enlarged plan view of a region around a driving IC chip 50 of a liquid crystal display device according to a second modification. For convenience of explanation, bump electrodes 51 and wirings 14 are not shown in FIG. 8.

As shown in FIG. 8, the support member 90 may be provided between at least a portion of the periphery of the driving IC chip 50 and the active matrix substrate 10. With this structure, the support member 90 can be prevented from inhibiting the flow of an insulating resin during formation of the anisotropic electrically conductive layer 60.

### Third Modification

### Modification of the First Preferred Embodiment

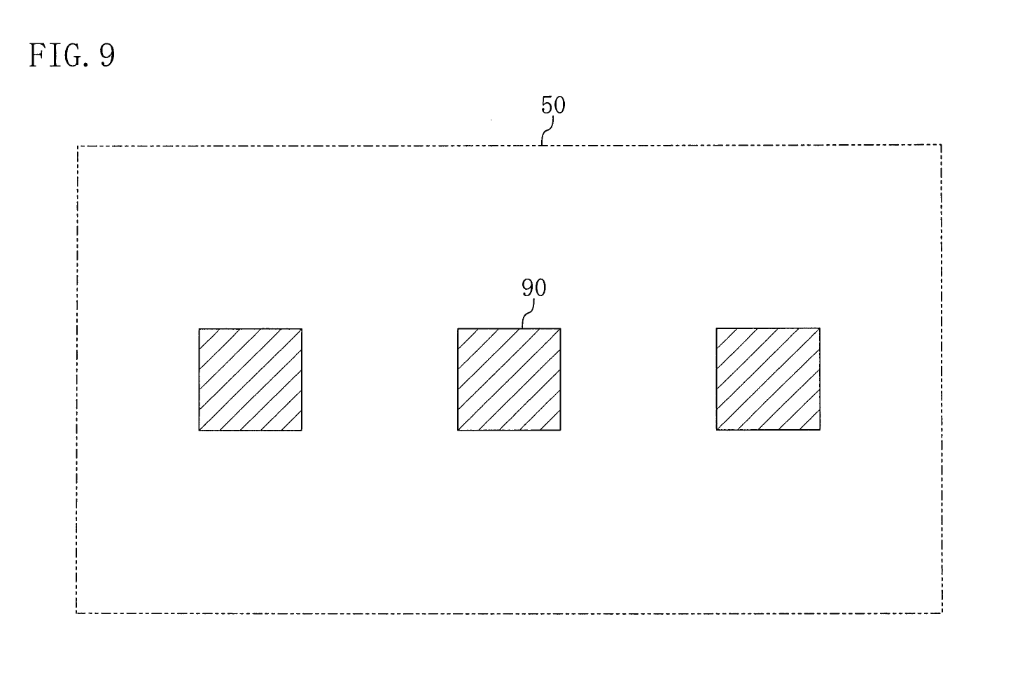

FIG. 9 is an enlarged plan view of a region around a driving IC chip 50 of a liquid crystal display device according to a third modification. For convenience of explanation, bump electrodes 51 and wirings 14 are not shown in FIG. 9.

As shown in FIG. 9, a support member 90 having a substantially rectangular cylindrical shape may be provided in the central region of the driving IC chip 50, that is, the region that does not have the bump electrodes 51 and is not in contact with the wirings 14. This structure can eliminate non-uniformity of pressure application resulting from warping and deformation of the active matrix substrate 10 in a preferable manner.

In this case, the support member 90 may further be provided between at least a portion of the periphery of the driving IC chip 50 and the active matrix substrate 10 as shown in FIGS. 3, 7, and 8. This structure can eliminate non-uniformity of pressure application resulting from the tilt between the pressure bonding stage and the pressure bonding tool and non-uniformity of pressure application resulting from warping and deformation of the active matrix substrate 10 in a preferable manner.

### Second Preferred Embodiment

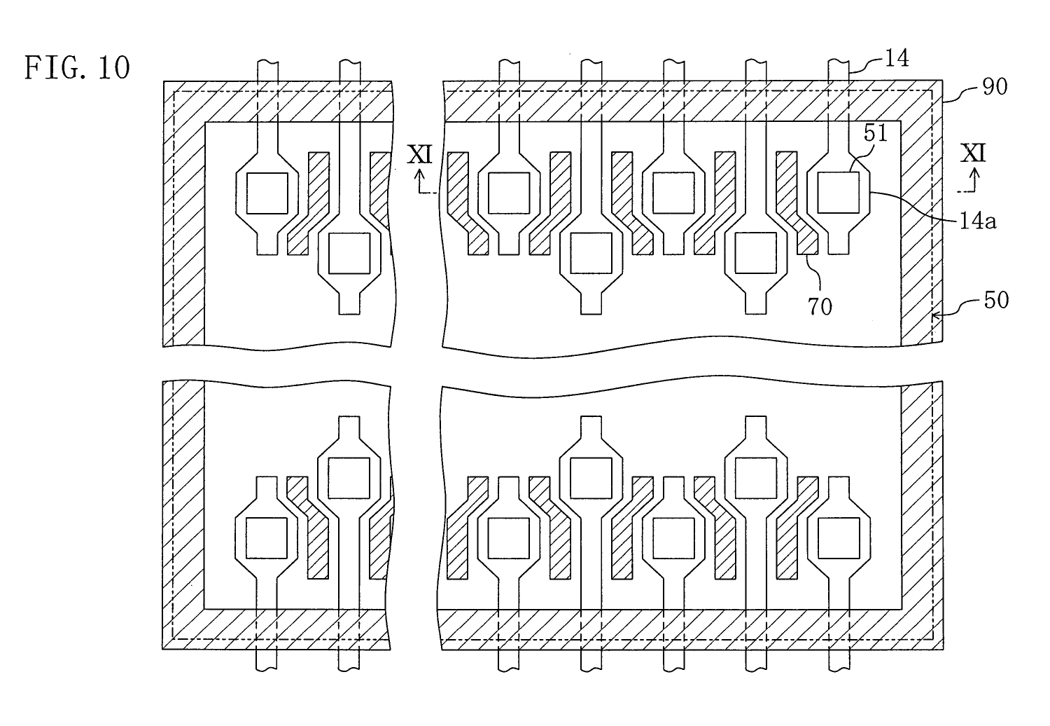

FIG. 10 is an enlarged plan view of a region around a driving IC chip 50 of a liquid crystal display device according to a second preferred embodiment of the present invention.

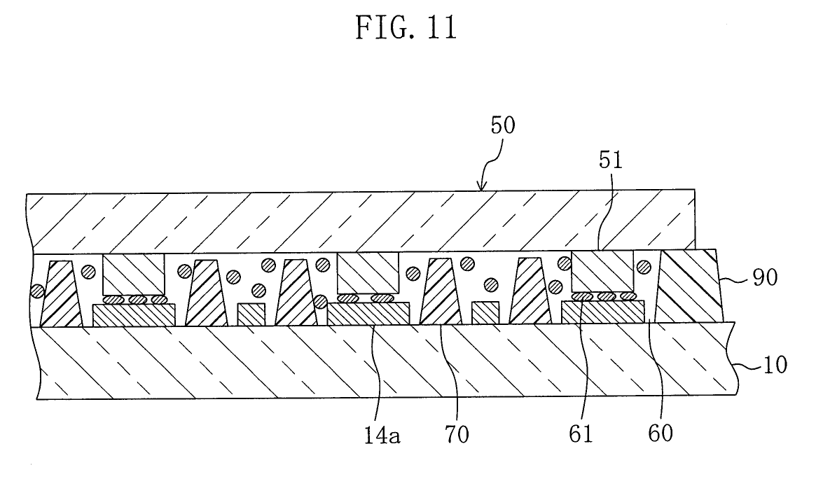

FIG. 11 is a cross-sectional view taken along line XI-XI in FIG. 10.

The liquid crystal display device of the second preferred embodiment is preferably the same as the liquid crystal display device 1 of the first preferred embodiment except that the liquid crystal display device of the second preferred embodiment further includes an insulating member 70. The insulating member 70 will now be described in detail. Note that FIGS. 1 and 2 referred to in the first preferred embodiment are also referred to in the second preferred embodiment. Elements having substantially the same function as in the first preferred embodiment will be denoted by the same reference numerals and characters and description thereof will be omitted.

The liquid crystal display device of the second preferred embodiment has an insulating member (an insulating wall). The insulating member 70 isolates each terminal portion 14a from a wiring 14 and a bump electrode 51 that are located adjacent to that terminal portion 14a and also isolates a bump electrode 51 facing that terminal portion 14a from a bump electrode 51 and a wiring 14 that are located adjacent to that bump electrode 51. More specifically, the insulating member 70 is provided between each terminal portion 14a on the active matrix substrate 10 and a wiring 14 located adjacent to that terminal portion 14a.

For example, in the case where the insulating member 70 is not provided, the electrically conductive fine particles 61 in the anisotropic electrically conductive layer 60 may cause short-circuiting between adjacent wirings 14, between adjacent bump electrodes 51, or between the wiring 14 and the bump electrode 51, and a leakage current may be generated. Such short-circuiting is likely to occur especially in following cases: in the case where the anisotropic electrically conductive layer 60 containing the electrically conductive fine particles 61 at high concentration is used in order to reliably electrically connect the terminal portions 14a with the bump electrodes 51; in the case where a fine-pitch driving IC chip 50 is used in which the bump electrodes 51 are arranged at narrow intervals; and the like.

However, providing the insulating member 70 between adjacent terminal portions 14a as in the second preferred embodiment can effectively suppress generation of leakage current resulting from a short-circuit between adjacent wirings 14, between adjacent bump electrodes 51, or between the wiring 14 and the bump electrode 51.

The insulating member 70 may be arranged entirely along a portion of each wiring 14 that is in contact with the anisotropic electrically conductive layer 60. The terminal portion 14a is wider than the portion other than the terminal portion 14a of the wiring 14. Therefore, the space between each terminal portion 14a and a wiring 14 adjacent to that terminal portion 14a is relatively narrow. Therefore, for example in the case where the insulating member 70 is not provided, a leakage current is likely to be generated between a terminal portion 14a and a wiring 14 adjacent to the terminal portion 14a. In the second preferred embodiment, however, as shown in FIG. 10, the insulating member 70 is provided in the relatively narrow space between each terminal portion 14a and a wiring 14 adjacent to that terminal portion 14a. Therefore, generation of leakage current can be effectively suppressed.

As shown in FIG. 11, the insulating member 70 preferably has an approximately trapezoidal shape in cross section. In order to effectively suppress generation of leakage current, the top surface of the insulating member 70 preferably has a narrow width. More preferably, the width of the top surface of the insulating member 70 is equal to or less than the particle size (more specifically, mean particle size) of the electrically conductive fine particles 61.

In order to effectively suppress generation of leakage current, the top surface of the insulating member 70 is preferably in contact with the driving IC chip 50. However, the top surface of the insulating member 70 need not necessarily be in contact with the driving IC chip 50. As shown in FIG. 11, there may be a gap between the insulating member 70 and the driving IC chip 50. Even when there is a gap between the insulating member 70 and the driving IC chip 50, generation of leakage current can be suppressed as compared to the case where the insulating member 70 is not provided. The gap between the insulating member 70 and the driving IC chip 50 is preferably equal to or less than the particle size (more specifically, mean particle size; e.g., about 3 μm to about 5 μm, for example) of the electrically conductive fine particles 61. With this structure, the electrically conductive fine particles 61 can be effectively prevented from being disposed between the insulating member 70 and the driving IC chip 50. In this case, the height of the insulating member 70 is shown by, e.g., the following formula I, where H is the height of the insulating member 70, h1 is the cell gap of the liquid crystal layer 40, h2 is the height of the bump electrode 51, h3 is the height of the terminal portion 14a, r is the particle size of the electrically conductive fine particles 61, and A is the oblateness of the electrically conductive fine particles 61:

h1−r=h2+h3+r×(1−A)−r≦H≦h2+h3+r×(1−A)=h1 (1).

For example, the height of the insulating member 70 may be in the range of about 3 μm to about 25 μm (e.g., about 10 μm), for example.

For example, the insulating member 70 is preferably made of an acrylic resin, a novolac resin, a polyimide resin, an epoxy resin, or the like. The insulating member 70 and the support member 90 may be made of the same material. The insulating member 70 and the support member 90 may be formed from the same film by the same step.

In the case where the anisotropic electrically conductive layer 60 is formed by a wet process, it is preferable to apply a liquid repellent property (a property to repel ink for forming the anisotropic electrically conductive layer 60) to the surface of the insulating member 70. This can effectively suppress short-circuiting between the wirings 14, between the bump electrodes 51, or between the wiring 14 and the bump electrode 51, and therefore can effectively suppress generation of leakage current.

Note that examples of a method for applying a liquid repellent property to the surface of the insulating member 70 include a method in which the insulating member 70 is made of a fluorine-containing material having a liquid repellent property and a method in which liquid repellent treatment such as plasma treatment is conducted to the surface of the insulating member 70 after the insulating member 70 is formed.

### Fourth Modification

### Modification of the Second Preferred Embodiment

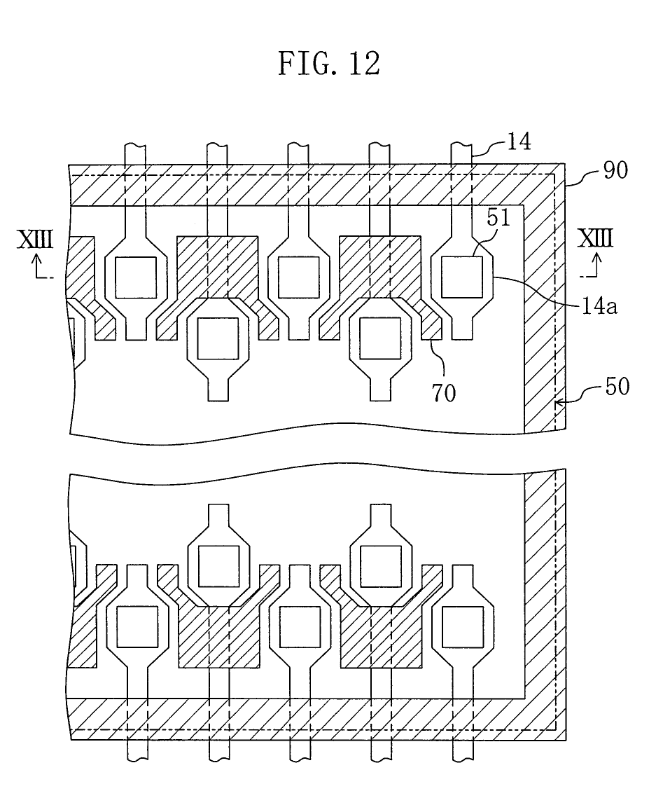

FIG. 12 is an enlarged plan view of a region around a driving IC chip of a liquid crystal display device according to a fourth modification.

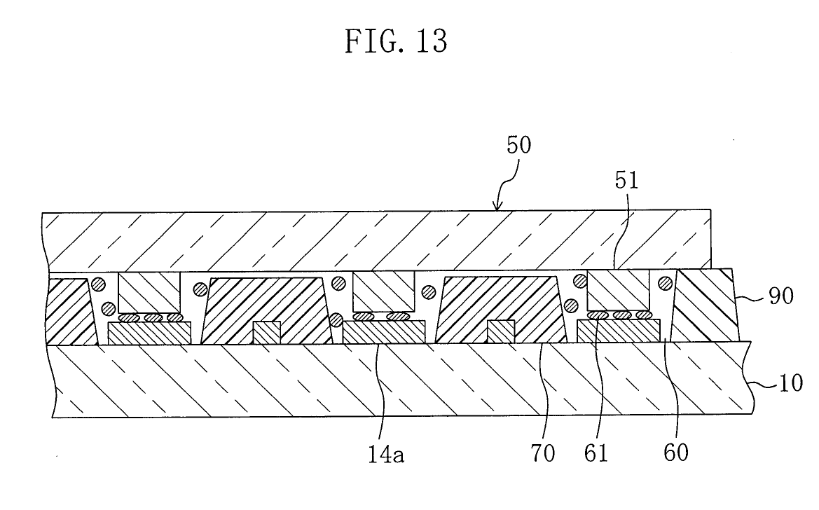

FIG. 13 is a cross-sectional view of a portion take along line XIII-XIII in FIG. 12.

As shown in FIGS. 12 and 13, adjacent insulating members 70 may be connected together so as to extend across the wiring 14. This structure can more effectively suppress generation of leakage current between a terminal portion 14a and a wiring 14 adjacent to the terminal portion 14a.

### Fifth Modification

### Modification of the Second Preferred Embodiment

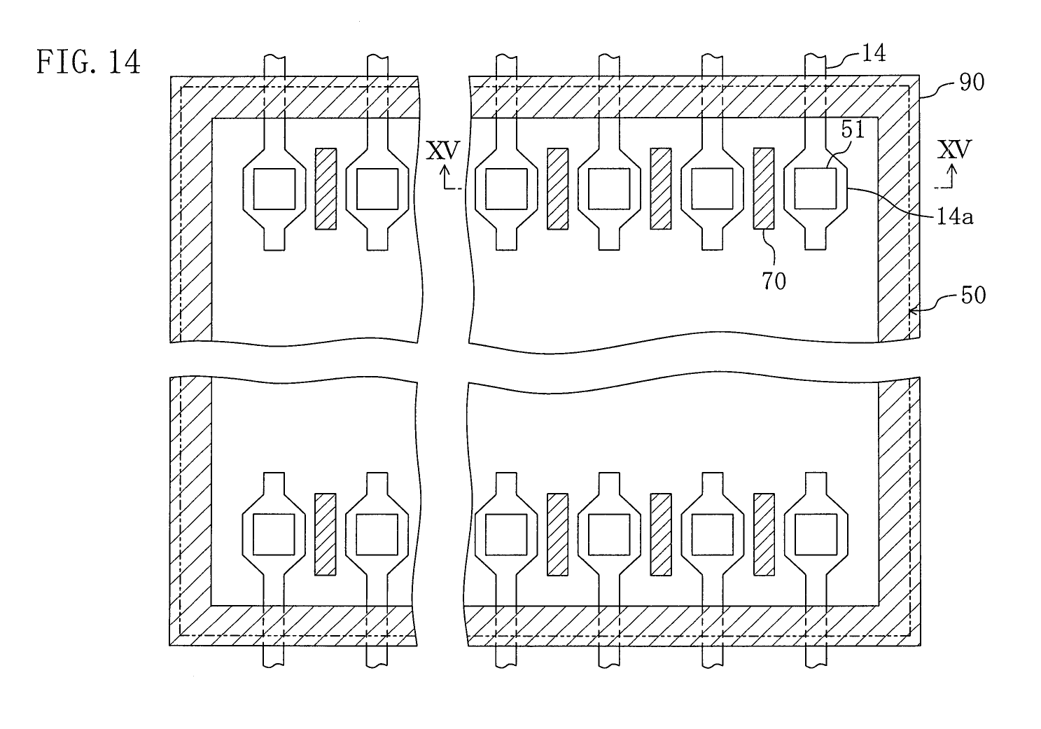

FIG. 14 is an enlarged plan view of a region around a driving IC chip 50 of a liquid crystal display device according to a fifth modification.

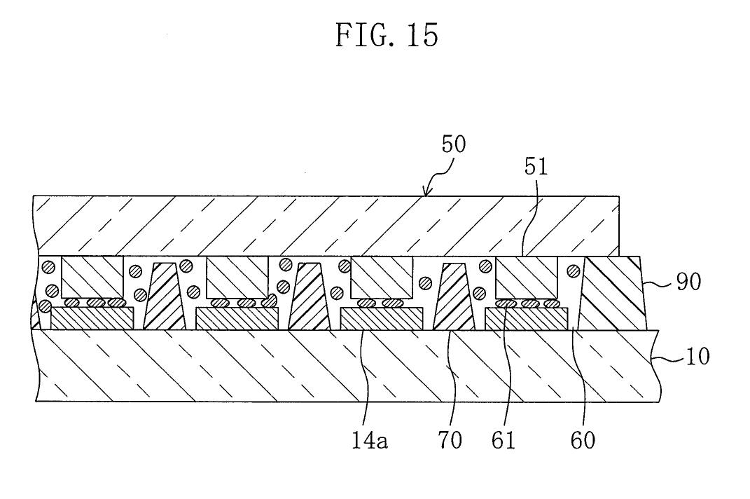

FIG. 15 is a cross-sectional view taken along line XV-XV in FIG. 14.

Bump electrodes 51 are linearly arranged in line along the direction of the longer side of the driving IC chip 50 (the width direction of the terminal portions 14a). The terminal portion 14a is wider than the portion other than the terminal portion 14a of the wiring 14. Therefore, in the fifth modification, the space between adjacent terminal portions 14a is relatively narrow, while the space between the portions other than the terminal portions 14a of the wirings 14 and the space between the portion other than the terminal portion 14a of each wiring 14 and an adjacent terminal portion 14a are relatively wide. Therefore, in this structure, generation of leakage current can be effectively suppressed by providing the insulating member 70 between the terminal portions 14a as shown in FIG. 14.

### Sixth Modification

### Modification of the Fifth Modification

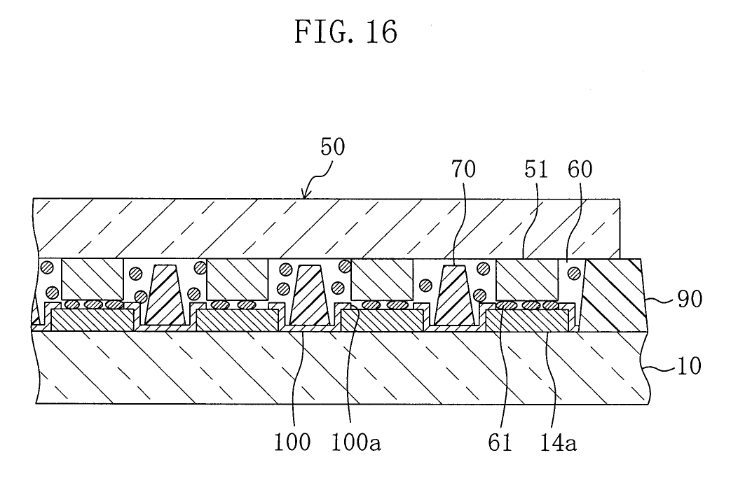

FIG. 16 is an enlarged cross-sectional view of a region around a driving IC chip 50 of a liquid crystal display device according to a sixth modification.

As shown in FIG. 16, an insulating layer 100 may be formed on the surface of the periphery of the active matrix substrate 10. The insulating layer 100 covers the wirings 14 and has openings 100a that expose the terminal portions 14a. This structure can very effectively suppress short-circuiting between the wirings 14.

### Third Preferred Embodiment

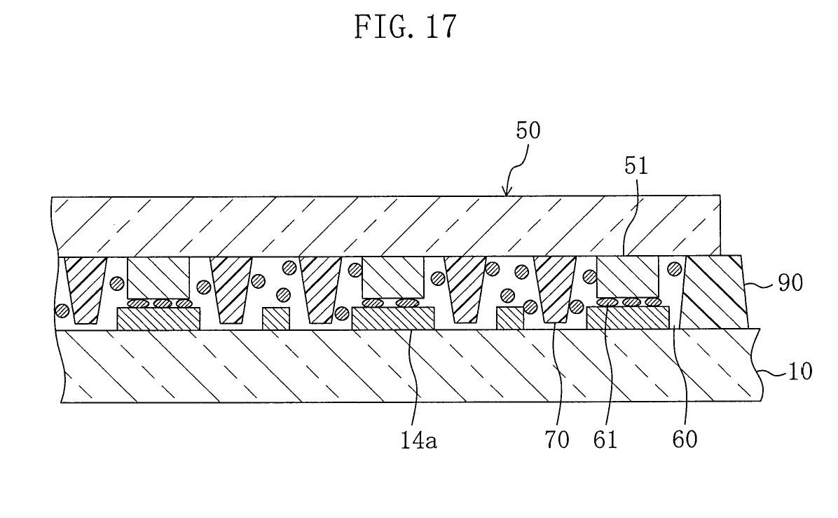

FIG. 17 is an enlarged cross-sectional view of a region around a driving IC chip 50 of a liquid crystal display device according to a third preferred embodiment.

A liquid crystal display device of the third preferred embodiment has the same structure as that of the liquid crystal display device of the second preferred embodiment except for the arrangement of the insulating members 70. The arrangement of the insulating members 70 of the third preferred embodiment will be described with reference to FIG. 17. Note that FIGS. 1, 2, 5A, and 5B referred to in the second preferred embodiment are also referred to in the third preferred embodiment. Elements having substantially the same function as in the second preferred embodiment will be denoted by the same reference numerals and characters and description thereof will be omitted.

In the second preferred embodiment, the insulating member 70 is provided between adjacent wirings 14 on the active matrix substrate 10. In the third preferred embodiment, the insulating member 70 is provided between adjacent bump electrodes 51 on the driving IC chip 50. The gap between the top of the insulating member 70 and the active matrix substrate 10 is equal to or less than the particle size (mean particle size) of the electrically conductive fine particles 61. This structure can also effectively suppress generation of leakage current between adjacent bump electrodes 51, between adjacent wirings 14, and between the bump electrode 51 and the wiring 14, as in the case where the insulating members 70 are provided on the active matrix substrate 10. As shown in FIG. 17, the insulating member 70 preferably has an approximately trapezoidal shape in cross section with a width reduced from the driving IC chip 50 toward the active matrix substrate 10. More preferably, the width of the top surface of the insulating member 70 is equal to or less than the particle size (mean particle size) of the electrically conductive fine particles 61. This can more effectively suppress generation of leakage current.

### Fourth Preferred Embodiment

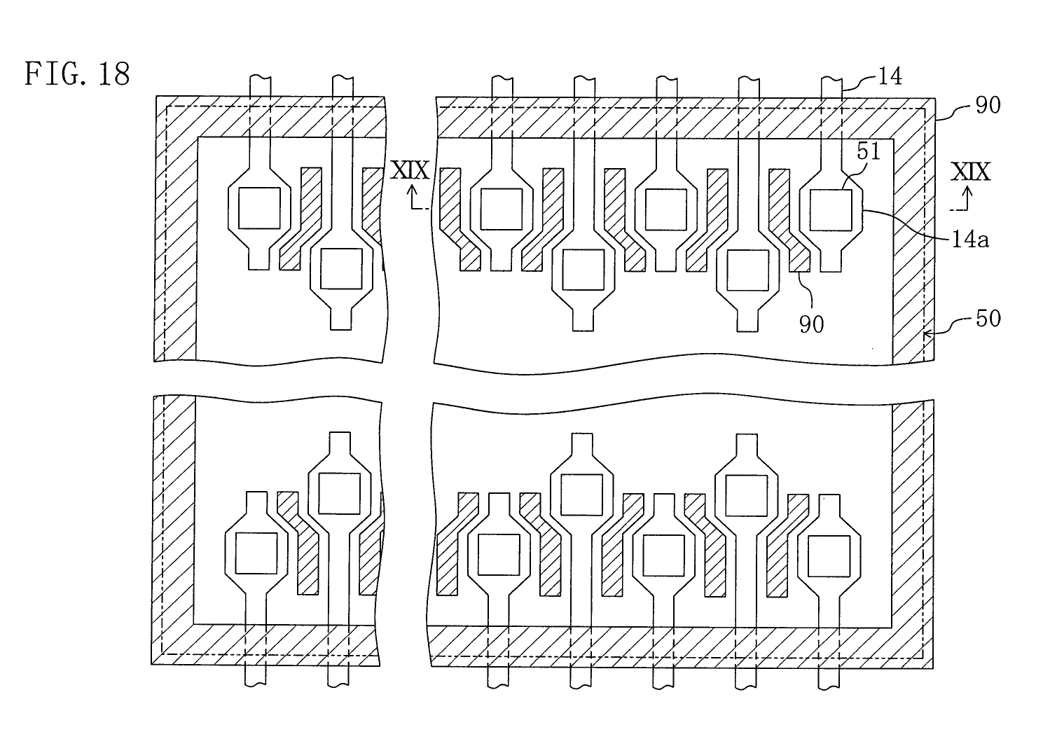

FIG. 18 is an enlarged plan view of a region around a driving IC chip 50 of a liquid crystal display device according to a fourth preferred embodiment.

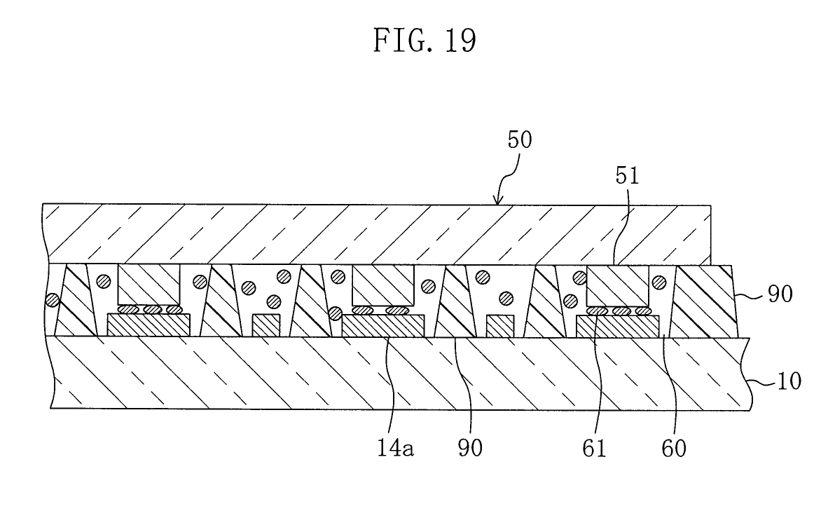

FIG. 19 is a cross-sectional view taken along line XIX-XIX in FIG. 18.

The liquid crystal display device of the fourth preferred embodiment preferably has the same structure as that of the liquid crystal display device 1 of the first preferred embodiment except that the support member 90 is further provided between adjacent wirings 14. The structure and functions of the support member 90 provided between adjacent wirings 14 will now be described in detail. Note that FIGS. 1 and 2 referred to in the first preferred embodiment are also referred to in the fourth preferred embodiment. Elements having substantially the same function as in the second preferred embodiment will be denoted by the same reference numerals and characters and description thereof will be omitted.

As described in detail in the first preferred embodiment and the like, providing the support member 90 between at least a portion of the periphery of the driving IC chip 50 and the active matrix substrate 10 can reduce the tilt between the driving IC chip 50 and the active matrix substrate 10 in the mounting process (the heating-pressurizing process) (the tilt between the pressure bonding stage and the pressure bonding tool). By further providing the support member 90 in each space between adjacent wirings 14 as in this preferred embodiment, the tilt between the driving IC chip 50 and the active matrix substrate 10 can be more effectively reduced. As a result, the driving IC chip 50 can be mounted with high reliability.

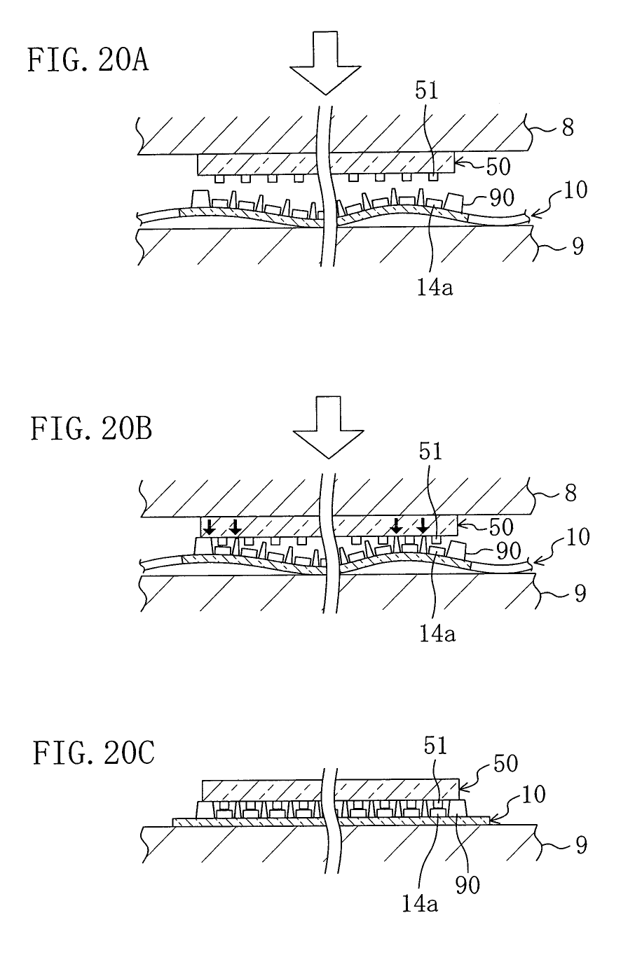

By providing the support member 90 between the wirings 14, defective mounting resulting from deformation of the active matrix substrate 10 such as warping and undulation can be effectively suppressed. The reason for this will now be described in detail with reference to FIGS. 20A, 20B, and 20C.

FIGS. 20A, 20B, and 20C are schematic cross-sectional views illustrating a mounting process in the fourth preferred embodiment. More specifically, FIG. 20A is a schematic cross-sectional view of the state before application of pressure. FIG. 20B is a schematic cross-sectional view of the state during application of pressure. FIG. 20C is a schematic cross-sectional view of the state when mounting is completed.

The active matrix substrate 10 is formed by a lamination of a plurality of members having different thermal expansion coefficients. Therefore, in the mounting process involving the heating step, internal stress is generated in the active matrix substrate 10 by thermal expansion (or thermal contraction) of each member. This may cause deformation of the active matrix substrate 10 such as warping and undulation. Especially in the case where the first substrate 11 is made of plastic or thin glass, the first substrate 11 may be significantly deformed due to its relatively low rigidity. In the case where the active matrix substrate 10 is deformed as shown in FIG. 20A, the support members 90 provided between the wirings 14 first contact the driving IC chip 50 in the raised region of the active matrix substrate 10 in the heating-pressurizing process shown in FIG. 20B. Since the raised region is pressed by these support members 90, the active matrix substrate 10 is flattened by the support members 90 as the heating-pressurizing process progresses in the mounting process. Accordingly, the terminal portions 14a can be electrically connected to the respective bump electrodes 51 in a preferable manner as shown in FIG. 20C. As a result, the driving IC chip 50 can be mounted with high reliability.

In the fourth preferred embodiment, the support member 90 is provided between the wirings 14 and isolates adjacent wirings 14 and adjacent bump electrodes 51 from each other. In other words, the support member 90 provided between the wirings 14 functions also as an insulating member 70, and effectively prevents short-circuiting from occurring between adjacent wirings 14, between adjacent bump electrodes 51, or between the wiring 14 and the bump electrode 51 by the electrically conductive fine particles 61 in the anisotropic electrically conductive layer 60. Accordingly, generation of leakage current can be effectively suppressed by providing the support member 90 between the wirings 14 as in this preferred embodiment.

In the fourth preferred embodiment, the terminal portions 14a having a wider width are arranged in a staggered pattern along the width direction of the terminal portions 14a (the longitudinal direction of the driving IC chip 50). Therefore, the gap between each terminal portion 14a and the wiring 14 adjacent to that terminal portion 14a is relatively narrow, and a short-circuit is likely to occur in this region. However, since the insulating member 70 is provided in this relatively narrow space between the terminal portion 14a and the wiring 14 as shown in FIG. 18, generation of leakage current can be effectively suppressed.

### Fifth Preferred Embodiment

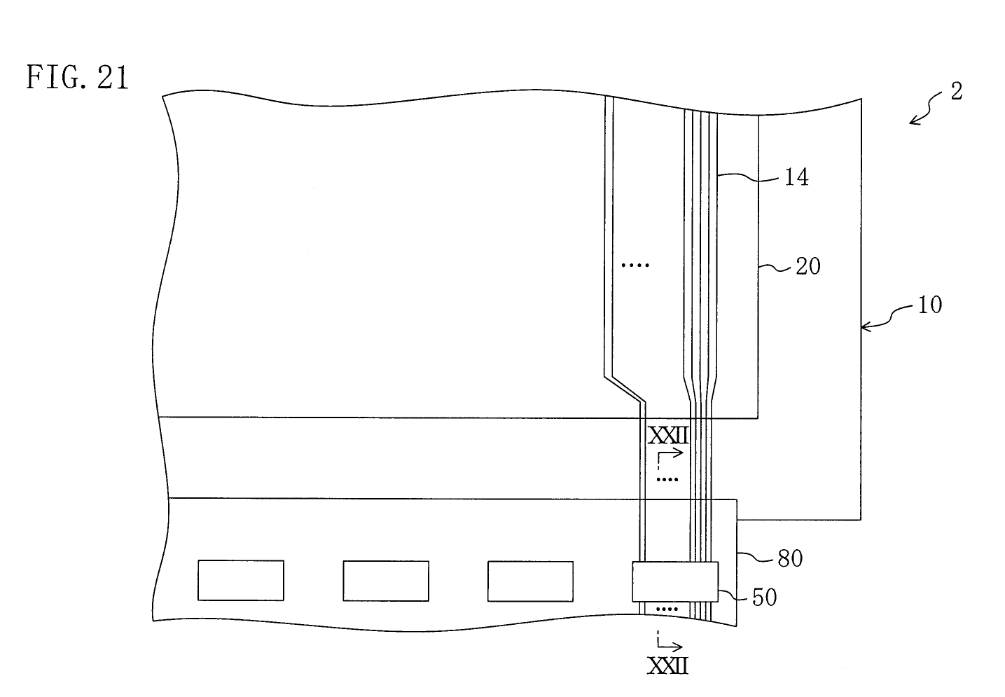

FIG. 21 is a plan view of a liquid crystal display device 2 according to a fifth preferred embodiment.

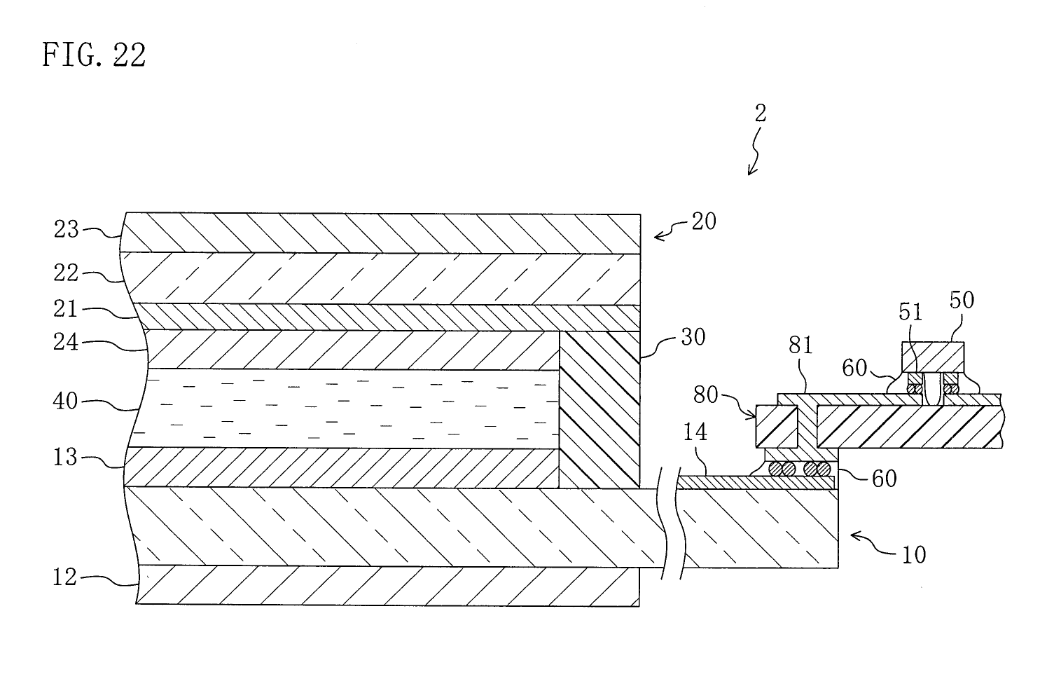

FIG. 22 is a cross-sectional view taken along line XXII-XXII in FIG. 21.

The liquid crystal display device 2 of the fifth preferred embodiment includes an active matrix substrate 10, a counter substrate 20 facing the active matrix substrate 10, a liquid crystal layer 40 provided between the active matrix substrate 10 and the counter substrate 20 and serving as a display medium layer, a seal member 30 bonding the active matrix substrate 10 with the counter substrate 20 and sealing the liquid crystal layer 40, and a flexible printed circuit board 80 (hereinafter, sometimes referred to as an “FPC board 80”) mounted on the on the active matrix substrate 10.

The active matrix substrate 10 has a first substrate 11 made of plastic or glass, and a first polarizing plate 12 provided on the opposite side to the liquid crystal layer 40 on the first substrate 11. A plurality of gate lines and a plurality of source lines are provided on the active matrix substrate 10. The plurality of gate lines extend in parallel or substantially in parallel with each other and the plurality of source lines extend in parallel or substantially in parallel with each other at an angle (typically at right angle) to the extending direction of the gate lines. A switching element (not shown) such as a TFT element is provided near each intersection of the gate lines and the source lines. Each switching element is electrically connected to a corresponding gate line and a corresponding source line. A plurality of pixel electrodes 13 are arranged in a prescribed pattern (typically, in a matrix pattern) on the surface of the active matrix substrate 10 located on the side of the liquid crystal layer 40. Each pixel electrode 13 is electrically connected to a corresponding switching element (not shown) and is driven by that switching element.

The counter substrate 20 has a second substrate 22, a second polarizing plate 23 provided on the opposite side to the liquid crystal layer 40 on the second substrate 22, and an upper common electrode 21 provided on the surface of the second substrate 22 on the side of the liquid crystal layer 40. The liquid crystal display device 2 is driven by a voltage that is applied to the liquid crystal layer 40 by the upper common electrode 21 and the plurality of pixel electrodes 13 provided on the active matrix substrate 10.

In the fifth preferred embodiment, the active matrix substrate 10 is larger than the counter substrate 20, and wirings 14 are provided in the periphery of the active matrix substrate 10 which is not covered by the counter substrate 20. As shown in FIG. 22, printed wirings 81 are provided on the FPC board 80. The printed wirings 81 are electrically connected to the wirings 14 through the anisotropic electrically conductive layer 60. Each printed wiring 81 has a terminal portion 81a. The driving IC chip 50 is mounted so that each terminal portion 81a is electrically connected to a corresponding bump electrode 51 of the driving IC chip 50.

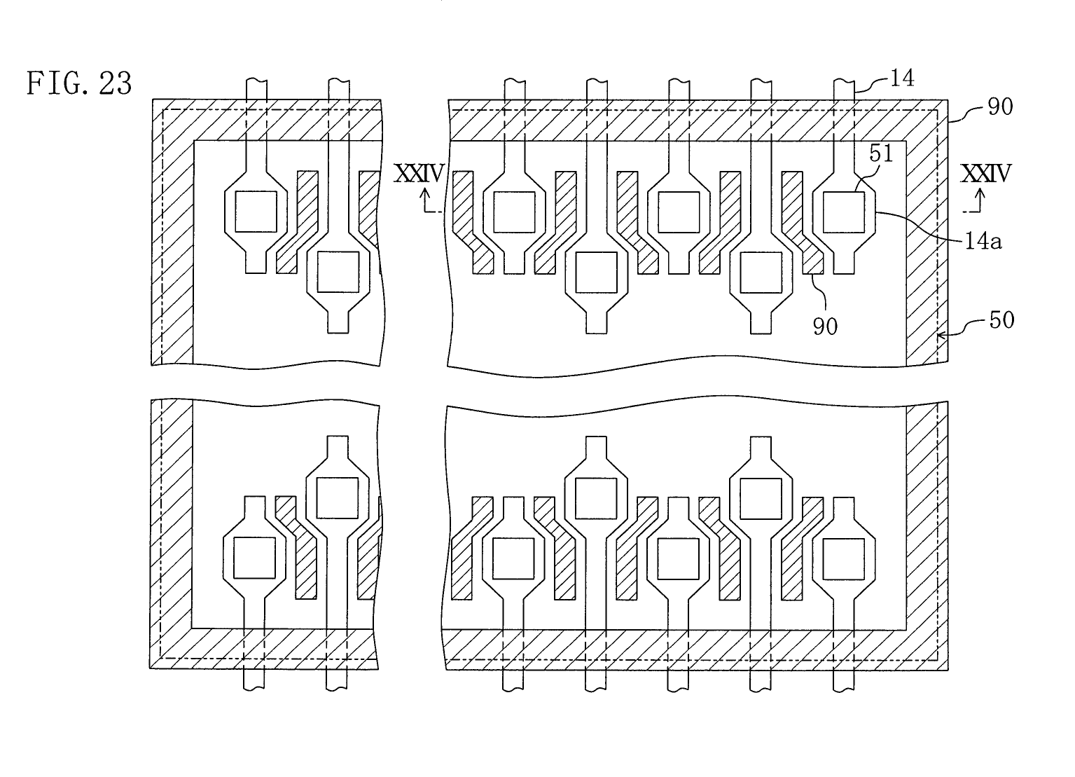

FIG. 23 is an enlarged plan view of a region around the driving IC chip 50.

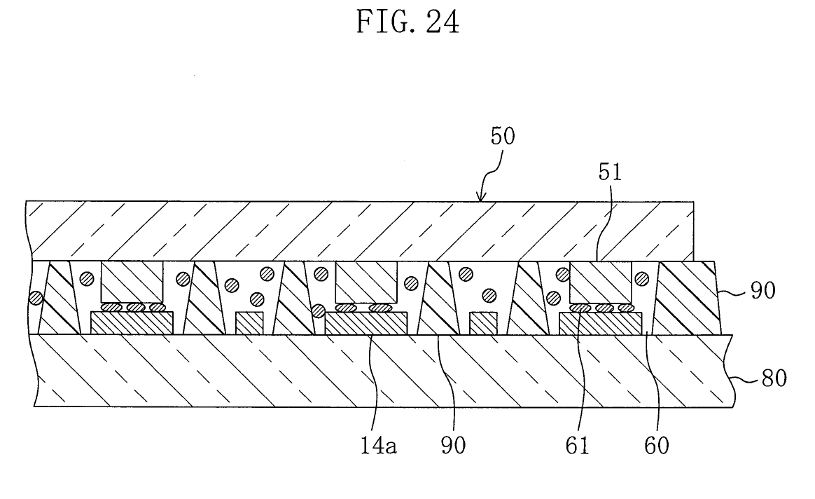

FIG. 24 is a cross-sectional view taken along line XXIV-XXIV in FIG. 23.

As shown in FIGS. 23 and 24, the driving IC chip 50 has a plurality of bump electrodes 51 as input/output terminals. The bump electrodes 51 are arranged in a staggered pattern along the direction of the longer side of the driving IC chip 50 (the width direction of the terminal portions 81a). The bump electrodes 51 function also as bonding bump electrodes. The bump electrodes 51 are respectively electrically connected through the anisotropic electrically conductive layer 60 to the terminal portions 18a of the printed wirings 81. The anisotropic electrically conductive layer 60 is made of an insulating resin with electrically conductive fine particles 61 dispersed therein.

In the liquid crystal display device 2 of this preferred embodiment, the support member 90 is arranged in contact with the driving IC chip 50 and the FPC board 80. More specifically, the support member 90 is shaped like a wall and extends as a band so as to surround the driving IC chip 50. Therefore, the tilt of the pressure bonding tool 9 with respect to the pressure bonding stage 8 is reduced as described in the first preferred embodiment, and the pressure is relatively uniformly applied between each terminal portion 81a and the corresponding bump electrode 51. As a result, the driving IC chip 50 can be mounted with high reliability.

The support member 90 preferably has an insulating property. In the case where the support member 90 is electrically conductive, short-circuiting may occur between the terminal portions 81a, between the terminal portion 81a and the bump electrode 51, and the like through the electrically conductive fine particles 61 dispersed in the anisotropic electrically conductive layer 60 and the support member 90. As a result, a leakage current may be generated. By using the support member 90 having an insulating property, such short-circuiting caused by the support member 90 can be prevented and generation of leakage current can be effectively suppressed.

In the fifth preferred embodiment, the support member 90 is also provided between adjacent printed wirings 81. Therefore, the tilt between the driving IC chip 50 and the FPC board 80 can be more effectively reduced. As a result, the driving IC chip 50 can be mounted with high reliability. By providing the support member 90 between the printed wirings 81, defective mounting resulting from deformation of the FPC board 80 such as warping and undulation can be effectively suppressed.

In the fifth preferred embodiment, the support member 90 is provided between the printed wirings 81 and isolates adjacent printed wirings 81 and adjacent bump electrodes 51 from each other. The support member 90 provided between the wirings 14 thus functions also as an insulating member 70, and effectively prevents short-circuiting from occurring between adjacent printed wirings 81, between adjacent bump electrodes 51, or between the printed wiring 81 and the bump electrode 51 by the electrically conductive fine particles 61 in the anisotropic electrically conductive layer 60. Accordingly, generation of leakage current can be effectively suppressed by providing the support member 90 between the printed wirings 81 as in this preferred embodiment.

In the fifth preferred embodiment, the terminal portions 81a having a wider width are arranged in a staggered pattern along the width direction of the terminal portions 81a (the longitudinal direction of the driving IC chip 50). Therefore, the gap between each terminal portion 81a and the printed wiring 81 adjacent to that terminal portion 81a is relatively narrow, and short-circuiting is likely to occur in this region. In this preferred embodiment, however, as shown in FIG. 23, the support member 90 functioning also as an insulating member 70 is provided in this relatively narrow region between each terminal portion 81a and the printed wiring 81 adjacent to the terminal portion 81a. Therefore, generation of leakage current can be effectively suppressed.

### Other Modifications

Although a display device having a driving IC chip 50 mounted on a substrate with an anisotropic electrically conductive layer interposed therebetween has been described in the first through fifth preferred embodiments and their modifications, a mounting method of the driving IC chip 50 is not limited in the present invention. For example, the driving IC chip 50 may be mounted with solder or may be mounted directly on a substrate without interposing an electrically conductive material therebetween.

Although an active matrix type liquid crystal display device has been described in the first through fifth preferred embodiments and their modifications, the present invention is not limited to this. For example, the present invention includes a passive matrix type liquid crystal display device, a segment type liquid crystal display device, each of these types of organic electroluminescence display device, inorganic electroluminescence display device, plasma display device, and field emission display device, and the like.

Although a flexible printed board is mounted in a liquid crystal display device in the fifth preferred embodiment, the present invention is not limited to this. For example, a flexible printed board may be mounted in electronic equipment apparatuses such as a communication apparatus, an acoustic apparatus, a computing apparatus, and an information processing apparatus.

As has been described above, a wiring substrate according to various preferred embodiments of the present invention can effectively suppress defective mounting. Therefore, the present invention is useful for cellular phones, PDAs (Personal Digital Assistances), television sets, electronic books, monitors, electronic posters, clocks, inventory tags, emergency guide signs, and the like.

While preferred embodiments of the present invention have been described above, it is to be understood that variations and modifications will be apparent to those skilled in the art without departing the scope and spirit of the present invention. The scope of the present invention, therefore, is to be determined solely by the following claims.

1-21. (canceled)

22: A wiring substrate, comprising:
a substrate;
a plurality of wirings extending substantially in parallel with each other on the substrate and each having a terminal portion;
an integrated circuit chip arranged so as to face the substrate and having a plurality of bump electrodes electrically connected to the respective terminal portions; and
a support member located between the substrate and the integrated circuit chip so as to be in contact with both the substrate and the integrated circuit chip.

23: The wiring substrate according to claim 22, wherein the support member has an insulating property.

24: The wiring substrate according to claim 22, wherein the support member is located between at least a portion of a periphery of the integrated circuit chip and the substrate.

25: The wiring substrate according to claim 22, wherein the support member has a wall-shaped configuration and extends so as to surround the integrated circuit chip.

26: The wiring substrate according to claim 22, wherein the support member is located between each of four corners of the integrated circuit and the substrate.

27: The wiring substrate according to claim 22, wherein the support member is located between adjacent wirings on the substrate.

28: The wiring substrate according to claim 22, wherein the substrate is made of plastic.

29: The wiring substrate according to claim 22, further comprising:
an anisotropic electrically conductive adhesive layer disposed between the substrate and the integrated circuit chip and made of an insulating resin having electrically conductive fine particles dispersed therein to electrically connect the terminal portions to the plurality of bump electrodes; and
an insulating member arranged to isolate each terminal portion from a wiring and a bump electrode that are adjacent to the terminal portion and isolating a bump electrode facing the terminal portion from a bump electrode and a wiring that are adjacent to the bump electrode.

30: The wiring substrate according to claim 29, wherein the insulating member is located between each terminal portion and a wiring adjacent to the terminal portion on the substrate, and a gap between a top of the insulating member and the integrated circuit chip is equal to or less than a particle size of the electrically conductive fine particles.

31: The wiring substrate according to claim 29, wherein the insulating member is located between adjacent bump electrodes on the integrated circuit chip, and a gap between a top of the insulating member and the substrate is equal to or less than a particle size of the electrically conductive fine particles.

32: The wiring substrate according to claim 29, wherein each terminal portion is wider than a portion other than the terminal portion of the wiring and the terminal portions are linearly arranged in a width direction of the terminal portions, and the insulating member is located only between adjacent terminal portions.

33: The wiring substrate according to claim 29, wherein each terminal portion is wider than a portion other than the terminal portion of the wiring and the terminal portions are arranged in a staggered pattern along a width direction of the terminal portions, and the insulating member is disposed only between each terminal portion and a wiring adjacent to the terminal portion.

34: The wiring substrate according to claim 30, wherein the insulating member has an approximately trapezoidal shape in cross section with a width reduced from the substrate toward the integrated circuit chip.

35: The wiring substrate according to claim 31, wherein the insulating member has an approximately trapezoidal shape in cross section with a width reduced from the integrated circuit chip toward the substrate.

36: The wiring substrate according to claim 34, wherein a width of a top surface of the insulating member is equal to or less than the particle size of the electrically conductive fine particles.

37: The wiring substrate according to claim 30, wherein the insulating member is in contact with both the substrate and the integrated circuit chip.

38: The wiring substrate according to claim 29, wherein the anisotropic electrically conductive layer is made of wet processed material.

39: The wiring substrate according to claim 38, wherein a side surface and a top surface of the insulating member has a liquid repellent property.

40: A display device, comprising:
a wiring substrate including a substrate, a plurality of wirings extending substantially in parallel with each other on the substrate and each having a terminal portion, an integrated circuit chip arranged so as to face the substrate, a plurality of bump electrodes located on a surface of the integrated circuit chip on a side of the substrate and electrically connected to the respective terminal portions, a support member located between the substrate and the integrated circuit chip so as to be in contact with both the substrate and the integrated circuit chip, and a first electrode electrically connected to the plurality of wirings;
a display medium layer located on the first electrode; and
a second electrode located on the display medium layer.

41: A display device, comprising:
a first wiring substrate including a substrate, a plurality of first wirings extending substantially in parallel with each other on the substrate and each having a terminal portion, an integrated circuit chip arranged so as to face the substrate, a plurality of bump electrodes located on a surface of the integrated circuit chip on a side of the substrate and electrically connected to the respective terminal portions, and a support member disposed between the substrate and the integrated circuit chip so as to be in contact with both the substrate and the integrated circuit chip;
a second wiring substrate having the first wiring substrate mounted thereon and including a plurality of second wirings respectively electrically connected to the plurality of first wirings and a first electrode electrically connected to the plurality of second wirings;
a display medium layer located on the first electrode; and
a second electrode located on the display medium layer.

42: The display device according to claim 40, wherein the display medium layer is a liquid crystal layer.
